(19) United States
(12) Patent Application Publication
(10) Pub. No.: US 2011/0256482 A1
(43) Pub. Date: Oct. 20, 2011

(54) PHOTOSENSITIVE RESIN COMPOSITION, METHOD OF MANUFACTURE THEREOF AND ARTICLES INCLUDING THE SAME

(75) Inventor: Suwa TATSUHIRO, Yokohama (JP)

(73) Assignee: SAMSUNG ELECTRONICS CO., LTD., Suwon-si (KR)

(21) Appl. No.: 13/035,303

(22) Filed: Feb. 25, 2011

(30) Foreign Application Priority Data
Apr. 14, 2010 (JP) 2010-093422

(51) Int. Cl. G03F 7/004; G03F 7/20

(52) U.S. Cl. 430/287.1; 430/319

(57) ABSTRACT

Provided herein is a photosensitive resin composition which is patternable and exhibits adhesion even after being crosslinked. The photosensitive resin composition includes a (meth)acryl-based polymer having a carboxyl group and a reactive double bond on a side chain and having a specific acid value and a specific content of reactive double bond, and a photopolymerization initiator.

### CROSS-REFERENCE TO RELATED APPLICATION

This application claims the benefit of Japanese Patent Application No. 2010-093422, filed on Apr. 14, 2010, and all the benefits accruing therefrom under 35 U.S.C. §119, the content of which in its entirety is herein incorporated by reference as if fully set forth herein.

### BACKGROUND

1) Field

The disclosure relates to a photosensitive resin composition, method of manufacture thereof, and articles including the same, and more particularly, to a photosensitive resin composition capable of being patterned by exposure and development and exhibiting adhesion even after being patterned.

2) Description of the Related Art

Current methods of manufacturing a semiconductor or printed circuit board (“PCB”) use a photosensitive resin composition to pattern a metal to provide a selected shape. A photosensitive resin composition can be a dry film resist, which is provided as a film-type product and which does not include a solvent. When a dry film resist is used to manufacture a PCB, for example, coating and drying processes can be omitted and the PCB manufacturing process can be a continuous process. Hence, due to various advantages, such as ease of handling, the dry film resist has been widely adopted.

As an example of a commercially practiced technique using the dry film resist, an active energy ray-curable resin applicable to the manufacture of a protective layer of a color filter or a PCB is disclosed in Japanese Patent Application Publication No. 2004-300266. After being cured, a layer of the active energy ray curable resin has a modulus of 2.3 gigaPascals (GPa).

Commercially available dry film resists do not provide sufficient adhesion. For example, disclosed in Japanese Patent Application Publication No. 2004-300266 is a dry film resist, however when this dry film resist (an ultra violet curable resin) is exposed and cross-linked, it forms a very rigid thin layer that cannot be removed or relocated.

Also, although a commercially available adhesive sheet material may be used to attach an adhesive to an adherent, such a material cannot be readily patterned. Thus there remains a need for a photosensitive resin composition, which can be patterned by exposure and development, and which provides adhesion after being patterned.

### SUMMARY

Disclosed herein is a photosensitive resin composition, which can be patterned by exposure and development, and which provides adhesion after being patterned.

Disclosed is a photosensitive resin composition including: about 100 parts by weight of a (meth)acryl polymer including a carboxyl group, and a reactive double bond on a side chain, wherein the (meth)acryl polymer has an acid value of about 65 to about 180 KOH milligrams per gram, and a content of a monomer unit including the reactive double bond of about 0.5 to about 18 mole percent, based on a total content of monomer units in the (meth)acryl polymer; and about 0.5 to about 10 parts by weight of a photopolymerization initiator, wherein the content of the (meth)acryl polymer and the content of the photopolymerization initiator are based on the total weight of the (meth)acryl polymer and the photopolymerization initiator.

In an embodiment, the photosensitive resin composition can be patterned by exposure and development, and it provides adhesion after being patterned.

Disclosed is an adhesive film including the photosensitive resin composition.

Disclosed is a method of patterning a semiconductor. The method includes: disposing the film comprising the photosensitive resin composition on a substrate; disposing a mask on the film; irradiating the mask and the film for a time effective to crosslink a portion of the photosensitive resin composition exposed by the mask; and contacting the irradiated film with an alkali development solution to form a pattern on the semiconductor. Alternatively, the method includes: disposing the photosensitive resin composition of claim 1 on a substrate to form a film comprising the photosensitive composition; disposing a mask on the film; irradiating the mask and the film to crosslink an exposed portion of the photosensitive resin composition; and contacting the irradiated film comprising the crosslinked portion of the photosensitive resin composition with an alkali development solution to form a pattern on the semiconductor.

Also disclosed is a method of preparing a photosensitive resin composition. The method includes contacting a monomer including a carboxyl group, and a monomer including a reactive functional group, to provide a copolymer; contacting the copolymer with a compound including a reactive double bond and a group capable of reacting with a reactive functional group, to provide a (meth)acryl polymer, wherein the (meth)acryl polymer has an acid value of about 65 to about 180 KOH milligrams per gram, and a content of a monomer unit including the reactive double bond of about 0.5 to about 18 mole percent, based on a total content of monomer units in the (meth)acryl polymer; and contacting 100 parts by weight of the (meth)acryl polymer with about 0.5 to about 10 parts by weight of a photopolymerization initiator, based on the total weight of the (meth)acryl polymer and the photopolymerization initiator, to prepare the photosensitive resin composition.

### DETAILED DESCRIPTION

The invention now will be described more fully hereinafter with reference to the accompanying drawings, in which a non-limiting embodiment is shown. This invention may, however, may be embodied in many different forms, and should not be construed as limited to the embodiments set forth herein. Rather, these embodiments are provided so that this disclosure will be thorough and complete, and will fully convey the scope of the invention to those of ordinary skill in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer, or section from another element, component, region, layer or section. Thus, a first element, component, region, layer, or section discussed below could be termed a second element, component, region, layer, or section without departing from the teachings of the present invention.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” or “includes” and/or “including” when used in this specification, specify the presence of stated regions, integers, steps, operations, elements, and/or components, but do not preclude the presence or addition of one or more other regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The term “(meth)acryl” used herein is a generic term for an acryl (which includes both acrylics and acrylates) and a methacryl (which includes both acrylics and acrylates). Thus, a compound having the prefix (meth), such as (meth)acrylic acid, may refer to compounds having the prefix “meth” and compounds not having the prefix “meth.”

“Alkyl” refers to a straight or branched chain saturated aliphatic hydrocarbon having the specified number of carbon atoms, for example, 1 to 12 carbon atoms, or 1 to 6 carbon atoms. Alkyl groups include, for example, groups having from 1 to 50 carbon atoms (C1 to C50 alkyl).

“Aryl” refers to a cyclic moiety in which all ring members are carbon and at least one ring is aromatic, the moiety having the specified number of carbon atoms, for example, 6 to 24 carbon atoms, or 6 to 12 carbon atoms. More than one ring may be present, and any additional rings may be independently aromatic, saturated or partially unsaturated, and may be fused, pendant, spirocyclic or a combination thereof.

“Amine” refers to a group of the general formula NRR, wherein each R is independently hydrogen, an alkyl group, or an aryl group.

In an embodiment, a photosensitive resin composition includes: 100 parts by weight of a (meth)acryl polymer comprising a carboxyl group, and a reactive double bond on a side chain, wherein the (meth)acryl polymer has an acid value of about 65 to about 180 KOH milligrams per gram (mg/g), and a content of a monomer unit comprising the reactive double bond is about 0.5 to about 18 mole percent (mol %), based on a total content of monomer units of the (meth)acryl polymer; and about 0.5 to about 10 parts by weight of a photopolymerization initiator, wherein the content of the (meth)acryl polymer and the content of the photopolymerization initiator are based on the total weight of the (meth)acryl polymer and the photopolymerization initiator.

A polymer itself in a commercially available dry film resist is rarely crosslinked because it has few reactive double bonds in the polymer. Instead, an oligomer is generally added as a crosslinking agent to the commercially available dry film resist. Accordingly, radiation (such as ultraviolet (“UV”) radiation) is applied so that the crosslinking agent is polymerized (e.g., bound together), to provide a net-like structure. When the crosslinking agent is reacted, the polymer is bound (e.g., fixed) to the net-like structure, and the polymer effectively cannot be moved after the crosslinking A molecular weight between the crosslinking points, is equal to or less than a molecular weight of the oligomer, and a modulus of the cured material after UV application is significantly greater than a modulus before UV application. Accordingly, some polymers in the resist may have a high modulus, e.g., a modulus of about 10⁷ to about 10¹¹, or about 10⁸ to about 10¹⁰, or about 10⁹ Pa after crosslinking. As further disclosed above, the dry film resist may have poor adhesion after being crosslinked.

A (meth)acryl polymer of the photosensitive resin composition according to an exemplary embodiment has a selected amount of a reactive double bond on a side chain thereof. Sufficiently energetic radiation, such as a UV ray, may be applied through a photomask having a desired pattern, and a portion of the photosensitive resin composition to which the radiation is applied may be crosslinked and cured, by, for example, creating a radical which reacts with the reactive double bond. A portion of the photosensitive resin composition to which the radiation is not applied is not cured, and has an acid value in a selected range, which provides alkali solubility. Thus the unexposed portion of the photosensitive resin composition may be removed by contacting the unexposed portion of the photosensitive resin composition with an alkali development solution. In further detail, the portion of photosensitive resin composition to which the radiation (e.g., the UV ray) is not applied may be substantially or completely removed by the alkali development solution to form a pattern.

Herein, if the total content of monomer units of the (meth)acryl polymer is 100 mol %, the content of the reactive double bond on the side chains of the (meth)acryl polymer is about 0.5 to about 18 mol %, or about 1 to about 15 mol %, or about 2 to about 12 mol %. The photosensitive resin composition may provide adhesion after being crosslinked and patterned, and provide adhesion after being crosslinked (i.e., cured) by, for example, exposure to the UV ray. While not wanting to be bound by theory, this mechanism is further disclosed below, but shall not limiting.

The reactive double bond is present on the side chain of the (meth)acryl polymer, wherein the (meth)acryl polymer may be a linear polymer. It is believed that the reactive double bond is opened (e.g., broken) by a radical which is generated by the UV ray, and then a new bond is formed with another reactive double bond situated nearby. As a result, the resulting polymer has a net-like structure. Herein, when the content of the reactive double bond is selected to be in the above range, the portion of the photosensitive resin in which the reactive double bonds are bound to each other, e.g., the length of the molecule between the crosslinking points (e.g., the molecular weight between the crosslinking points), is also adequately selected, and the resulting polymer exhibits adhesion.

It is generally known that tackiness, which is an indication of adhesion, is related to a modulus of a material. At room temperature, an uppermost value of a modulus of a polymer exhibiting adhesion is approximately 10⁵ to about 10⁶ Pa. If a polymer has a modulus exceeding this range, the polymer is generally considered not to have adhesion.

Accordingly, a resin composition that provides adhesion and is photosensitive can be obtained by selecting the content of the reactive double bond on the side chain of the (meth)acryl polymer to be in a specific range to indirectly control the modulus as well as the molecular weight between the crosslinking points. Moreover, at the same time, the photosensitive resin also has a selected amount of compressibility after being crosslinked As the result of intensive investigation, it was unexpectedly found that the content of the reactive double bond in the polymer may be used to select an amount of adhesion suitable for good patternability and temporary fixation.

The disclosed photosensitive resin composition can be used in various applications to provide adhesion and patterning. The photosensitive resin composition can be used for example, to provide discrete positioning of parts, such as an IC chip, temporary fixation, or adhesion of a component that can later be peeled off during fabrication. In an embodiment, patterning can be performed to avoid (e.g., protect) a region which is not in contact with an adhesive resin of a product, such as a region in which an LCD panel and a touch panel are coupled. In addition, because the disclosed photosensitive resin composition has adequate compressibility after being crosslinked, it can be used to fill a gap, or to attach a second member having a gap. Furthermore, if a stress is created when the second member is attached, the stress may be substantially or completely absorbed by the photosensitive resin composition.

### (Meth)acryl Polymer

### Acid Value

In an embodiment, a (meth)acryl-based polymer of the photosensitive resin composition has an acid value of about 65 to about 180 KOH mg/g, or about 85 to 1 about 70 KOH mg/g, or about 90 to about 160 KOH mg/g, and may be developed to provide a selected pattern after being crosslinked using an alkali development solution. When the acid value is lower than about 65 KOH mg/g, the (meth)acryl polymer may be insoluble in the alkali development solution, and when the acid value is higher than about 180 KOH mg/g, the (meth)acryl polymer may be soluble in the alkali development solution or a resin layer may be released even when the degree of crosslinking is increased.

To control the acid value of the polymer in the above range, it is necessary to appropriately select a content of monomers containing a carboxyl group, wherein the first monomer corresponds to a monomer unit of the (meth)acryl polymer. The acid value used herein is a value calculated from the content of the monomer having the carboxyl group, based on a total content of monomers of the polymer.

### Content of Reactive Double Bonds

The content of reactive double bonds is about 0.5 to about 18 mol %, or about 0.7 to about 15 mol %, or about 1 to about 12 mol %, based on 100 mol % of the total content of the monomers of the (meth)acryl polymer. When the content of the reactive double bond is less than about 0.5 mol %, due, for example, to insufficient crosslinking after exposure, the resulting polymer may be so soft that the crosslinked (i.e., exposed) portion is undesirably soluble during development. In addition, when the content of the reactive double bond is more than about 18 mol %, a thin layer of the exposed portion may be so rigid that adhesion is reduced.

The content of the reactive double bond may be calculated on the basis of the monomer composition of the (meth)acryl polymer. To introduce the reactive double bond in to the (meth)acryl polymer, a monomer containing a reactive functional group may be copolymerized with the monomer containing a carboxyl group to provide a copolymer. The copolymer may then be reacted with a compound comprising a reactive double bond and a group capable of reacting with the reactive functional group of the monomer containing the reactive functional group so as to introduce the reactive double bond into a side chain of the (meth)acryl polymer. The compound having the group capable of reacting with the reactive functional group in the monomer containing the reactive functional group and the reactive double bond is considered to react with all the reactive functional groups of the monomers containing the reactive functional groups, and then the content of the reactive double bonds is calculated from the amount of the monomer containing reactive functional groups that is used.

As further disclosed above, in an embodiment the (meth)acryl polymer used in the photosensitive resin composition may be a polymer obtained by reacting the copolymer obtained by polymerizing the monomer containing the carboxyl group and the monomer containing the reactive functional group with the compound comprising the reactive double bond and the group capable of reacting with the reactive functional group.

Hereinafter, each monomer will be disclosed in further detail, but the disclosure shall not limited thereto.

### (A) Monomer Containing Carboxyl Group

To provide the selected acid value of the photosensitive resin composition, a monomer (A) comprising a carboxyl group (a) is used as as a monomer to produce the (meth)acryl polymer. The monomer comprising the carboxyl group (a) may be an unsaturated monomer having at least one carboxyl group in the molecule.

Examples of the monomer (A) comprising the carboxyl group (a) may include, but are not limited to, (meth)acrylic acid, maleic acid, maleic anhydride, fumaric acid, fumaric anhydride, crotonic acid, itaconic acid, itaconic anhydride, myristoleic acid, palmitoleic acid, or oleic acid. The foregoing may be used alone or in a combination comprising at least one of the foregoing. Among these, (meth)acrylic acid, maleic acid, maleic anhydride, fumaric acid, fumaric anhydride, crotonic acid, itaconic acid, or itaconic anhydride may be used. Also, (meth)acrylic acid may be used. The monomers containing the carboxyl groups may be used alone or in a combination comprising at least one of the foregoing.

A content of the monomer (A) comprising the carboxyl group (a) may be about 8 to about 24 parts by weight, or about 11 to about 23 parts by weight, or about 12 to about 22 parts by weight, based on a total weight of the (meth)acryl polymer.

### (B) Monomer Containing Reactive Functional Group

As further disclosed above, to introduce a reactive double bond into the (meth)acryl polymer of the photosensitive resin composition, the monomer (B) comprising a reactive functional group (b) may be used. The monomer (B) comprising the reactive functional group (b) and a compound (C) comprising a reactive double bond and a group (c) capable of reacting with a reactive functional group (to be described below) may be selected to provide a suitably reactive combination.

The monomer (B) comprising the reactive functional group (b) may be mono-functional or multi-functional, and may be selected to be mono-functional to more easily control a reactivity thereof. A multi-functional monomer can also be used, in consideration of a number of moles of the functional group and a group capable of reacting with a reactive functional group, which is further disclosed below.

Examples of the monomer (B) comprising the reactive functional group (b) may include a (meth)acryl monomer comprising a hydroxyl group, a (meth)acryl monomer comprising an isocyanate group, a (meth)acryl monomer comprising an amino group, a (meth)acryl monomer comprising an epoxy group, or a combination comprising at least one of the foregoing. The monomer comprising the reactive functional group (b) may be used alone or in combination. Further, synthesized or commercially available products may be used as the monomer.

The (meth)acryl monomer (B) comprising the hydroxyl group is an acrylic monomer having a hydroxyl group in the molecule. Examples of the (meth)acryl monomer comprising the hydroxyl group may include, but are not limited to, 2-hydroxyethyl(meth)acrylate, 4-hydroxybutyl(meth)acrylate, 1,6-hexanediol mono(meth)acrylate, pentaerythritol tri(meth)acrylate, dipentaerythritol(meth)acrylate, neopentyl glycol mono(meth)acrylate, trimethylopropane di(meth)acrylate, trimethyloethane di(meth)acrylate, 2-hydroxypropyl(meth)acrylate, 2-hydroxybutyl(meth)acrylate, 2-hydroxy-3-phenyloxypropyl(meth)acrylate, 4-hydroxycyclohexyl(meth)acrylate, N-2-hydroxyethyl(meth)acrylamide, cyclohexanedimethanol monoacrylate, or a combination comprising at least one of the foregoing. A compound obtained from an additive reaction of a compound comprising a glycidyl group, such as alkylglycidylether, arylglycidylether, or glycidyl(meth)acrylate, with (meth)acrylic acid may also be included.

An example of the (meth)acryl monomer (B) comprising the isocyanate group may include 2-acryloyloxyethyl isocyanate, 2-methacryloyloxyethyl isocyanate, 2-isocyanate ethyl(meth)acrylate, 3-isocyanate propyl(meth)acrylate, 4-isocyanate butyl(meth)acrylate, or a combination comprising at least one of the foregoing. Products such as KARENZ AOI® (2-acryloylethyl isocyanate), and KARENZ MOI® (2-methacryloyloxyethyl isocyanate) (produced by Showa Denko K. K.) are commercially available.

An example of the (meth)acryl monomer (B) comprising the amino acid may include t-butyl aminoethyl(meth)acrylate, ethyl aminoethyl(meth)acrylate, dimethyl aminoethyl(meth)acrylate, diethyl aminoethyl(meth)acrylate, N,N-dimethyl aminoethyl(meth)acrylate, N,N-diethyl aminoethyl(meth)acrylate, methacryloxyethyl trimethyl ammonium chloride(meth)acrylate, or a combination comprising at least one of the foregoing.

An example of the (meth)acryl monomer comprising the epoxy group may include glycidyl(meth)acrylate, β-methylglycidyl(meth)acrylate, aryl glycidyl ether, or a combination comprising at least one of the foregoing.

Among these, the monomer may be 2-hydroxyethyl(meth)acrylate, 4-hydroxybutyl(meth)acrylate, 2-hydroxyethyl(meth)acrylamide, cyclohexanedimethanol monoacrylate, or a combination comprising at least one of the foregoing. Also, the monomer may be 2-hydroxyethyl(meth)acrylate, 4-hydroxybutyl(meth)acrylate, N-2-hydroxyethyl(meth)acrylamide, or a combination comprising at least one of the foregoing. The monomer may also be 2-hydroxyethyl(meth)acrylate.

The amount of the monomer (B) comprising the reactive functional group may be about 0.5 to about 15 parts by weight, about 0.7 to about 14 parts by weight, or about 0.8 to about 13 parts by weight.

In an embodiment, a carboxyl group can also function as a reactive functional group (b). Examples of monomers containing carboxyl group (a) that can also function as a reactive group (b) are the same as those described above for monomer (A). Thus, a monomer (A) containing the carboxyl group (a) may also function as monomer (B) containing the reactive functional group (b). The content of the monomer (A) in this case may be about 8.5 to about 39 parts by weight, 1.7 to about 37 parts by weight, or about 12.8 to about 35 parts by weight, and the monomer (B) may be omitted, such that the amount of the monomer (B) may be 0. When the monomer (A) is contained in the above range, the composition can exhibit alkali solubility Further, when the carboxyl group (a) of monomer (A) is used as the reactive functional group (b), the amount of the compound (C) having a group (c) capable of reacting with a reactive functional group and a reactive double bond (d) (to be described below) may be selected such that the acid value of the (meth)acryl polymer and the content of the reactive double bond (d) satisfy the above ranges.

(C) Compound Comprising a Reactive Double Bond and a Group Capable of Reacting with the Reactive Functional Group

The term “reactive double bond” used herein refers to a double bond which may be used to form a new chemical bond when contacted by a radical generated from a photopolymerization initiator and radiation such as UV radiation. A compound having such a reactive double bond may be a compound having at least one ethylenic unsaturated double bond in a molecule. The ethylenic unsaturated double bond may be found in an acryl group (i.e., CH₂═CH—C(O)—), a methacryl group (i.e., CH═C(CH₃)—C(O)—), or a vinyl group (i.e., CH₂═CH—). Hereinafter, for clarity, the “compound comprising a reactive double bond and a group capable of reacting with the reactive functional group” may be referred to as a “reactive double bond compound.”

The reactive double bond compound (C) comprises a group (c) capable of reacting with a reactive functional group (b), which is included in a monomer unit of the (meth)acryl polymer main chain as well as a reactive double bond (d), wherein the reactive double bond (d) is introduced into a side chain of the polymer by reaction with the reactive functional group (b) of the monomer (A) or the monomer (B) containing the reactive functional group (b). Examples of the group (c) capable of reacting with the reactive functional group (b) may include, but are not limited to, a carboxyl group, a hydroxyl group, an epoxy group, an isocyanate group, an amino group, or a combination comprising at least one of the foregoing.

To introduce the reactive double bond (c) into the (meth)acryl polymer, it is necessary to select the reactive functional group (b) and the group (c) capable of reacting with the reactive functional group in the appropriate combination. The combination (b, c) may be (hydroxyl group, isocyanate group), (hydroxyl group, carboxyl group), (epoxy group, carboxyl group), (carboxyl group, epoxy group), (isocyanate group, hydroxyl group), (isocyanate group, carboxyl group), or (amino group, carboxyl group). Among these, the combination of a hydroxyl group and an isocyanate group or a combination of a carboxyl group and an epoxy group may be used to easily control the reaction. The reactive double bond compound (C) may be used alone or in combination. In addition, a synthesized or commercially available product may be used as the reactive double bond compound (C).

An example of the reactive double bond compound (C) comprising the isocyanate group may include methacryloyl isocyanate, 2-methacryloyloxyethyl isocyanate, 2-acryloyloxyethyl isocyanate, 2-methacryloyloxyethyl isocyanate, 1,1-bis(acryloyloxy methyl)ethyl isocyanate, m-isopropyl phenyl-α,α-dimethyl benzyl isocyanate, 2-isocyanate ethyl(meth)acrylate, 3-isocyanate propyl(meth)acrylate, 4-isocyanate butyl(meth)acrylate, or a combination comprising at least one of the foregoing. Products such as KARENZ AOI® (2-acryloylethyl isocyanate), and KARENZ MOI® (2-methacryloyloxyethyl isocyanate) (produced by Showa Denko K. K.) are commercially available.

An example of the reactive double bond compound (C) containing the hydroxyl group may include 2-hydroxyethyl(meth)acrylate, 4-hydroxybutyl(meth)acrylate, 1,6-hexanediol mono(meth)acrylate, pentaerythritol tri(meth)acrylate, dipentaerythritol penta(meth)acrylate, neopentyl glycol mono(meth)acrylate, trimethylopropane di(meth)acrylate, trimethyloethane di(meth)acrylate, 2-hydroxypropyl(meth)acrylate, 2-hydroxybutyl(meth)acrylate, 2-hydroxy-3-phenyloxy propyl(meth)acrylate, 4-hydroxycyclohexyl(meth)acrylate, N-2-hydroxyethyl(meth)acrylamide, cyclohexanedimethanol monoacrylate, or a combination comprising at least one of the foregoing. Further, the reactive double bond compound (C) comprising the hydroxyl group may include a compound obtained by addition of (meth)acrylic acid and a compound including a glycidyl group, such as alkylglycidylether, arylglycidylether, or glycidyl(meth)acrylate. ARONIX series materials, such as ARONIX M-554, M-154, M-555, M-155, and M-158 (produced by Toagosei Co., Ltd), BRENMAR® series materials, such as BRENMAR® PE-200, PE-350, PP-500, PP-800, PP-1000, 70 PEP-350 B, and 55 PET800 (produced by Nihon Yushi Co.) are commercially available.

Examples of the reactive double bond compound (C) comprising the amino group may include t-butyl aminoethyl(meth)acrylate, ethyl aminoethyl(meth)acrylate, dimethyl aminoethyl(meth)acrylate, diethyl aminoethyl(meth)acrylate, N,N-dimethyl aminoethyl(meth)acrylate, N,N-diethyl aminoethyl(meth)acrylate, methacryl oxyethyl trimethyl ammonium chloride(meth)acrylate, or a combination comprising at least one of the foregoing.

Examples of the reactive double bond compound (C) comprising the epoxy group may include a (meth)acrylic acid ester compound comprising an epoxy group, such as glycidyl(meth)acrylate, β-methylglycidyl(meth)acrylate, aryl glycidyl ether, α-ethyl glycidyl acrylate, crotonyl glycidyl ether, itaconic acid monoalkyl monoglycidyl ester, or a combination comprising at least one of the foregoing. CYCHROMA series materials, such as CYCHROMA A and M (produced by Daicel Chemical Industries, Ltd.) are commercially available.

Examples of the reactive double bond compound (C) comprising the carboxyl group may be the same as those described for the monomer (A) comprising the carboxyl group. ARONIX M-series materials such as ARONIX M-5300, 5400 and 5600 (produced by Toagosei Co., Ltd.), ACRYLESTER PA or HH (produced by Mitsubishi Rayon Co., Ltd.), LIGHT ACRYLATE HOA-HH (produced by Kyoeisha Chemical Co., Ltd), and NK ESTER SA and A-SA (produced by Shin-Nakamura Chemical Co., Ltd.) are commercially available.

The amount of the reactive double bond compound (C) to be used may be selected to be a molar ratio [(b)/(c)] of the reactive functional group (b) of the monomer containing the reactive functional group and the group (c) capable of reacting with the reactive functional group of the reactive double bond compound (C) of about 0.7 to about 1.3, or about 0.8 to about 1.2, or about 0.9 to about 1.1.

As further disclosed above, when the monomer (A) comprising the carboxyl group (a) serves as the monomer (B) containing the reactive functional group (b), the amount of the compound (C) having the group capable of reacting with the reactive functional group (b) and the reactive double bond used herein is selected such that the acid value of the (meth)acryl polymer and the content of the reactive double bond satisfies the above range. In an embodiment, in the (meth)acryl polymer, a portion of the monomer (A) containing the carboxyl group plays a role of the monomer (B) comprising the reactive functional group (b) to react with and bind to the reactive double bond compound (C), and the other portion of the monomer (A) may play a role of the monomer (A) comprising the carboxyl group to provide a carboxyl group (a). A ratio of the monomer (A) comprising the carboxyl group to the monomer (B) reacted to provide the reactive double bond, may be dependent on the amount of the reactive double bond-introduced compound (C) to be used, and a ratio of the monomer (C) used to introduce the reactive double bond to the monomer (A) serving to provide a carboxyl group may be about 1:50 to about 75:50, about 25:50 to about 50:50, or about 30:50 to about 40:50.

### (D) Other Copolymerizable Monomer

In an embodiment wherein in the (meth)acryl polymer, which is used in the photosensitive resin composition, comprises the monomer (A) comprising the carboxyl group and the monomer(B) comprising the reactive functional group (or where monomer (A) functions as monomer (B)), another copolymerizable monomer (D) may be further included.

The other copolymerizable monomer (D) may be a monomer capable of being copolymerized with the monomer (A) comprising the carboxyl group (a) and the monomer (B) comprising the reactive functional group (b). When the monomer (A) comprising the carboxyl group serves as the monomer (B) comprising the reactive functional group, the monomer (D) may be a monomer capable of being copolymerized with the monomer (A) comprising the carboxyl group.

Examples of the copolymerizable monomer (D) may include a (meth)acrylic acid ester monomer, an acrylic monomer having an amide group, an acrylic monomer having a urethane group, an acrylic vinyl monomer having a phenyl group, a vinyl monomer having a silane group, or a combination comprising at least one of the foregoing. To provide and better control adhesion, a (meth)acrylic acid ester monomer may be used. The copolymerizable monomer may be used alone or in combination. A synthesized or commercially available product may be used as the copolymerizable monomer.

The (meth)acrylic acid ester monomer may be an ester of (meth)acrylic acid not having a hydroxyl group in the molecule. Examples of the (meth)acrylic acid ester monomer may include, but are not limited to, methyl(meth)acrylate, ethyl(meth)acrylate, propyl(meth)acrylate, isopropyl(meth)acrylate, n-butyl(meth)acrylate, isobutyl(meth)acrylate, tert-butyl(meth)acrylate, isoamyl(meth)acrylate, n-hexyl(meth)acrylate, n-heptyl(meth)acrylate, n-octyl(meth)acrylate, tert-octyl(meth)acrylate, 2-ethyl hexyl(meth)acrylate, decyl(meth)acrylate, isodecyl(meth)acrylate, tridecyl(meth)acrylate, stearyl(meth)acrylate, isostearyl(meth)acrylate, phenyl(meth)acrylate, benzyl(meth)acrylate, dodecyl(meth)acrylate, tetrahydrofurfuryl(meth)acrylate, cyclohexyl(meth)acrylate, 4-n-butyl cyclohexyl(meth)acrylate, 2-ethylhexyl diglycol(meth)acrylate, butoxyethyl(meth)acrylate, butoxymethyl(meth)acrylate, 3-methoxybutyl(meth)acrylate, 2-(2-methoxy ethoxy)ethyl(meth)acrylate, 2-(2-butoxy ethoxy)ethyl(meth)acrylate, 4-butyl phenyl(meth)acrylate, phenyl(meth)acrylate, 2, 4, 5-tetramethyl phenyl(meth)acrylate, phenoxymethyl(meth)acrylate, phenoxyethyl(meth)acrylate, polyethylene oxide mono alkyl ether(meth)acrylate, polyethylene oxide mono alkyl ether(meth)acrylate, polypropylene oxide mono alkyl ether(meth)acrylate, trifluoroethyl(meth)acrylate, pentadeca fluoro oxyethyl(meth)acrylate, 2-chloro ethyl(meth)acrylate, 2,3-dibromopropyl(meth)acrylate, tribromo phenyl(meth)acrylate, or a combination comprising at least one of the foregoing.

Among these, methyl(meth)acrylate, ethyl(meth)acrylate, n-butyl(meth)acrylate, and 2-ethylhexyl(meth)acrylate may be used. Also, n-butyl(meth)acrylate, and 2-ethylhexyl(meth)acrylate may be used.

Examples of the acrylic monomer having the amide group may include (meth)acryl amide, N-methylol(meth)acrylamide, N-methoxy methyl(meth)acrylamide, N,N-methylene bis(meth)acrylamide, or a combination comprising at least one of the foregoing.

The acrylic monomer having the urethane group may be urethane(meth)acrylate.

Examples of the acrylic vinyl monomer having the phenyl group may include p-tert-butyl phenyl(meth)acrylate or o-biphenyl(meth)acrylate.

Examples of the vinyl monomer having the silane group may include 2-acetacetoxyethyl(meth)acrylate, vinyltrimethoxysilane, vinyltriethoxysilane, vinyltris([3-methoxy ethyl)silane, vinyltriacetylsilane, methacryloyl oxypropyl trimethoxysilane, or a combination comprising at least one of the foregoing.

In addition, styrene, chlorostyrene, α-methyl styrene, vinyl toluene, vinyl chloride, vinyl acetate, vinyl propionate, acrylonitrile, vinyl pyridine, or a combination comprising at least one of the foregoing may be used.

A content of the copolymerizable monomer (D) may be about 61 to about 91.5 parts by weight, about 63 to about 88.3 parts by weight, or about 65 to about 87.2 parts by weight, based on a total parts by weight of the copolymer produced from monomer (A), monomer (B) (if present) and monomer (D). In this range, the adhesion can be easily controlled. Among the above-mentioned copolymerizable monomers, the (meth)acrylic acid ester monomer may be used.

The total content of the monomer (A) containing the carboxyl group, the monomer (B) containing the reactive functional group, and the copolymerizable monomer (D) may be 100 parts by weight, based on a total weight of the (meth)acryl polymer.

### Method of Preparing (Meth)acryl Polymer

A method of preparing the (meth)acryl polymer having such a configuration is not particularly limited, but may include polymerizing a monomer (A) comprising a carboxyl group, a monomer (B) comprising a reactive functional group and a copolymerizable monomer (D), and introducing a reactive double bond into a side chain by reaction with a reactive double bond compound (C).

A method of polymerizing the monomer is not particularly limited, but may be one known to one of skill in the art and which may be determined without undue experimentation, and may include a method such as solution polymerization using a polymerization initiator, emulsion polymerization, suspension polymerization, inverse suspension polymerization, thin film polymerization, or spray polymerization. A method of controlling the polymerization may be adiabatic polymerization, temperature-controlled polymerization, or isothermal polymerization. Other than the method of initiating polymerization using a polymerization initiator, a method of initiating polymerization by applying radiation, an electron beam, or a UV ray may be used. The molecular weight may be selected and impurities reduced by use of solution polymerization using a polymerization initiator. For example, on the basis of 100 parts by weight of the total content of a monomer, about 70 to about 160, about 80 to about 150, or about 90 to about 140 parts by weight of ethyl acetate, toluene, or methyl ethyl ketone, as a solvent, and about 0.01 to about 0.50, about 0.1 to about 0.40, or about 0.2 to about 0.30 parts by weight of polymerization initiator are included to react in a nitrogen atmosphere at a temperature of about 60 to about 110° C., about 60 to about 75° C. for about 3 to about 10 hours, about 4 to about 9 hours, or about 5 to about 8 hours. The polymerization initiator may be added once, or at least twice.

An example of the polymerization initiator may include an azo compound, such as azobis isobutyronitrile (“AIBN”), 2,2′-azobis(2-methylbutyronitrile), azobiscyanovalerate, or a combination comprising at least one of the foregoing; an organic peroxide such as tert-butyl peroxy pivalate, tert-butylperoxybenzoate, tert-butyl peroxy-2-ethylhexanoate, di-tert-butylperoxide, cumene hydroperoxide, benzoyl peroxide, tert-butyl hydroperoxide, or a combination comprising at least one of the foregoing; or an inorganic peroxide such as hydrogen peroxide, ammonium persulfate, potassium persulfate, sodium persulfate, or a combination comprising at least one of the foregoing; or a combination comprising at least one of the foregoing. In an embodiment, azobis isobutyronitrile is used. The polymerization initiator may be used alone or in combination.

A reactive double bond-compound may be added to the polymer solution prepared as disclosed above and may be contacted (e.g., to react) at about 60 to about 120° C., about 70 to about 110° C., or about 80 to about 100° C. for about 4 to about 12 hours, about 5 to about 11 hours, or about 6 to about 10 hours. As a result, a (meth)acryl polymer having a reactive double bond at a side chain thereof may be obtained.

At this time, a catalyst may be added to regulate a reaction rate. The catalyst may be selected to correspond to a combination of a reactive functional group. For example, an amine catalyst may be used in an addition reaction of a carboxyl group with an epoxy group, an imide catalyst in a reaction of a carboxyl group with an amino group, or a metal catalyst in a reaction of a hydroxyl group with an isocyanate group.

### Glass Transition Temperature

The photosensitive resin composition including the (meth)acryl polymer having such a configuration exhibits adhesion even after being crosslinked A indicator for the adhesion is a glass transition temperature of the (meth)acryl polymer. The glass transition temperature (Tg) of the (meth)acryl polymer may range from about −60 to about −25° C., about −60 to about −30° C., or about −55 to about −35° C. Generally, properties of the polymer are significantly changed at more or less than the glass transition temperature. For example, a modulus of the polymer may be changed by a factor of 103. Many polymers exhibit adhesion at an atmospheric temperature higher than the glass transition temperature, which are particularly known among the acrylic polymers. The photosensitive resin composition according to an exemplary embodiment may have a glass transition temperature lower than the atmospheric temperature in which it will be used after being crosslinked, for example, a temperature of about 0 to about 40° C., about 5 to about 35° C., or about 10 to about 30° C.

The glass transition temperature according to an exemplary embodiment may have a value calculated using the Fox Equation. For example, the glass transition temperature (Tg) may be calculated by the following Equation 1:

1/Tg=Σ(Wᵢ/Tgᵢ) Equation 1

In Equation 1, Tg is a glass transition temperature of a polymer (having the units absolute temperature, K), Wᵢ is a weight fraction of a monomer i, and Tgᵢ is a glass transition temperature of a homopolymer composed of the monomer i (having the units absolute temperature, K).

In the disclosure, the glass transition temperature may be expressed in units of Celsius (° C.) and may be converted from the absolute temperature (K).

### Weight Average Molecular Weight

The (meth)aryl polymer may have a weight average molecular weight of about 10000 to about 300000, about 10000 to about 250000, or about 20000 to about 200000 Daltons. In this range, the polymer can have sufficient adhesion even after being crosslinked.

Further, the weight average molecular weight may be based on a polystyrene standard and obtained by the method disclosed in Table 1.

TABLE 1

| | |
|---|---|
| Device: | gel permeation chromatograph GPC |
| | (Model No. GPC-16) |
| Detector: | refractive index detector RI (Tosoh Co., |
| | Ltd., Model No. 8020, sensitivity 32) |
| | UV-VIS absorbance detector UV (Waters, |
| | 2487, wavelength: 215 nm, sensitivity: |
| | 0.2 AUFS) |
| Column: | 2 TSKgel GMHXL, 1 G2500HXL (Tosoh Co., |
| | Ltd.) (S/N M0052, M0051, N0010, |
| | Φ 7.8 mm × 30 cm) |
| Solvent: | tetrahydrofuran (Wako Pure Chemical |
| | Industries, Co.) |
| Fluid Rate: | 1.0 mL/min |
| Column Temperature: | 23° C. |
| Sample: | [concentration] about 0.2% |
| | [treatment] gentle agitation at room |
| | temperature |
| | [solubility] soluble (confirmed with eyes) |
| | [filtration] filtration with 0.45 μm |
| | filter |
| Injection Amount: | 0.200 ml |
| Standard Sample: | monodisperse polystyrene |
| Data Processing: | GPC data processing system |

### Photopolymerization Initiator

In an embodiment, the photosensitive resin composition includes a photopolymerization initiator to initiate a crosslinking reaction upon application of UV rays. The photopolymerization initiator refers to a radical polymerization initiator which can be activated by applying a UV ray having a wavelength of about 365 nanometers (nm) or less.

An example of the photopolymerization initiator may include an α-diketone, such as benzoin or diacetyl; a benzophenone, such as benzophenone; a p-hydroxybenzoic acid; an acyloin ester; an acetophenone such as acetophenone; xanthone or a thioxanthone; a halogen-containing compound such as chlorosulfonyl, a chloromethyl polynuclear aromatic compound, a chloromethyl heterocyclic compound, a chloromethyl benzophenone, or a combination comprising at least one of the foregoing; a triazine; a fluorenone; a haloalkane; an acridine; a redox couple such as a photoreducing pigment or a reducing agent; an organic sulfur compound; or a peroxide; or a combination comprising at least one of the foregoing.

For example, the photopolymerization initiator may include 2-methyl-1-(4-(methyl thio)phenyl)-2-morpholinopropane-1-on, 2-benzyl-2-dimethylamino-1-(4-morpholinophenyl)-butanone 1,1-hydroxy-cyclohexyl-phenyl-ketone, 2,2-dimethoxy-2-phenylacetophenone, 2-hydroxy-2-methyl-1-phenyl-propane-1-one, 2-benzyl-2-(dimethyl amino)-4-morpholinobutylphenone, 2-methyl-4′-(methyl thio)-2-morpholinopropiophenone, 1,7-(9-acrydinyl)hepthane, 2,2′-bis(o-chlorophenyl)-4,5,4′,5′-tetraphenyl-1,2′-biimidazole, 4,4′-dimethylaminobenzophenone, 4,4′-diethylethylaminobenzophenone, 7-(diethylamino)-4-methyl-2H-1-benzopyran-2-one, 7-(diethylamino)-4-methylcumarine, 4-dimethylamino ethyl benzoic acid, 2-dimethyl amino ethyl benzoic acid, 4-dimethyl amino ethyl benzoic acid (n-buthoxy), p-dimethyl amino benzoic acid isoamyl ethyl ester, 4-dimethyl amino 2-ethylhexyl benzoic acid, or 4,4′-diethylamino benzophenone, or a combination comprising at least one of the foregoing. Among these, the photopolymerization initiator may include 2-methyl-1-(4-(methylthio)phenyl)-2-morpholinopropane-1-one. The photosensitive initiator may be used alone or in combination.

An IRGACURE® series material such as IRGACURE® 907, 369, 184, or 819 (produced by Ciba Specialty chemicals); NISSOCURE MABP (produced by Nippon Soda Co., Ltd); EAB (produced by Hodogaya Chemical Co., Ltd); KAYACURE® EPA or KAYACURE® DMBI (produced by Nippon Kayaku Ltd); Quantacure DMB, QUANTACURE (produced by BEA International Bio-Synthetics); and ESOLOL 507 (produced by Van Dyk) are commercially available. Among these, IRGACURE® 907 may be used.

The photopolymerization initiator in the composition may be included in a content of about 0.5 to about 10 parts by weight, or about 1.0 to about 6.0 parts by weight, based on 100 parts by weight of the (meth)acryl polymer. When the content of the photopolymerization initiator is less than about 0.5 parts by weight, the radical initiator may be easily inactivated due to oxygen (resulting in decreased sensitivity), and when the content of the photopolymerization initiator is more than about 10 parts by weight, miscibility to the composition and stability of the composition may be decreased.

Cross linking Agent

In an embodiment, the photosensitive resin composition may further include a crosslinking agent. The disclosed (meth)acryl polymer has a reactive double bond on its side chain, and the reactive double bonds may be bound to each other by application of UV light. Therefore, the crosslinking agent may be omitted. However, as further disclosed above, because the molecular weight between the crosslinking points is relatively large, the crosslinking agent may be effectively used to stimulate the crosslinking reaction, and improve efficiency of the crosslinking reaction. In an embodiment, the crosslinking agent is included to improve the sensitivity of the photosensitive resin composition to UV. Due to the use of the crosslinking agent, a dose of the UV applied can be reduced, thereby reducing cost. Moreover, because the crosslinking reaction is stimulated, a manufacturing process can be accomplished in a shorter time.

A compound having at least one reactive double bond in the molecule may be used as the crosslinking agent. For example, the crosslinking agent may be dipentaerythritol hexaacrylate, trimethylpropanetriacrylate, trimethylolpropane trimethacrylate, pentaerythritol tetramethacrylate, ditrimethylolpropane tetramethacrylate, tris(acryloyloxyethyl) isocyanate, pentaerythritol tetraacrylate, ethylmethacrylate syrup, isobornyl methacrylate, dicyclopentanyl methacrylate, cyclohexyl methacrylate, isobornyl acrylate, dicyclopentanyl acrylate, tetradodecyl acrylate, or tricyclodecane methanol dimethacrylate, or a combination comprising at least one of the foregoing.

The crosslinking agent may be prepared by synthesizing the above compound or appropriately selected from a commercially-available product for a dry film resist. The product may include NK ESTER A-DPH, NK ESTER TMMT, NK ESTER D-TMP, or NK ESTER DCP (produced by Shin-Nakamura Chemical Co., Ltd), LIGHT ACRYLATE TMP-A, LIGHT ESTER TMP, LIGHT ACRYLATE PE-4 A, or LIGHT ACRYLATE IBX-A (produced by Kyoeisha Chemical Co.), ARONIX M-315 (produced by Toagosei Co., Ltd), CX1033 or TDA (produced by Mitsui Chemical Co.), ACRYESTER IBX (produced by Mitsubishi Rayon Co., Ltd), FA-513 M and FA-513 A (produced by Hitachi Chemical Co., Ltd), or BRENMAR® CHMA (produced by Nihon Yushi Co.), or a combination comprising at least one of the foregoing.

The crosslinking agent, which may be used to control the sensitivity of the photosensitive resin composition, may be added in an amount of about 1 to about 20 parts by weight, about 3 to about 15 parts, or about 4 to about 10 parts by weight, based on 100 parts by weight of the (meth)acryl polymer. In this range, the efficiency of the crosslinking reaction can be sufficiently increased.

### Another Additive

The photosensitive resin composition according to an exemplary embodiment may further include another additive. The other additive may include a curing stimulating agent, an inorganic filler, a softener, an anti-oxidizing agent, an anti-aging agent, a stabilizer, a tackifier, a modifier (e.g., a polyol resin, a phenol resin, an acryl resin, a polyester resin, a polyolefin resin, an epoxy resin, or an epoxidized polybutadiene resin), a silane coupling agent, a labeling agent, a foaming agent, a plasticizer, a dye, a pigment (e.g., a coloring pigment, or an extender pigment), a treatment agent, a viscosity control agent, a fluorescent whitening agent, a dispersing agent, a thermal stabilizer, a light stabilizer, an antistatic agent, a lubricant, or a solvent, or a combination comprising at least one of the foregoing.

An example of the curing stimulating agent may include DBTDL (Dibutyl tin Laurate), JCS-50 (Johoku Chemical Co., Ltd), or FORMATE TK-1 (Mitsui Takeda Chemicals Inc.).

An example of the antioxidizing agent may include dibutyl hydroxy toluene (“BHT”), IRGANOX® 1010, IRGANOX® 1035 FF, and IRGANOX® 565 (produced by Ciba Specialty Chemicals).

An example of the tackifer may include a rosin, such as rosin acid, synthetic rosin acid, or rosin acid ester, terpene resin, terpene phenol resin, aromatic hydrocarbon resin, aliphatic saturated hydrocarbon resin, or petroleum resin, or a combination comprising at least one of the foregoing.

An example of the silane coupling agent may include erythrimethoxysilane, diethylmethoxysilane, triethylmethoxysilane, n-propyltrimethoxysilane, ethyltrimethoxysilane, diethyldiethoxysilane, n-butyltrimethoxysilane, n-hexyltriethoxysilane, n-octyltrimethoxysilane, phenyltrimethoxysilane, diphenyldimethoxysilane, cyclohexylethyldimethoxysilane, vinyltrichlorosilane, vinyltrimethoxysilane, vinyltriethoxysilane, vinyltris(β-methoxyethoxy)silane, β-(3,4-epoxy cyclohexyl)ethyltrimethoxysilane, γ-glycidoxypropyltrimethoxysilane, γ-glycidoxypropyltriethoxysilane, γ-methacryloxypropylethyldimethoxysilane, γ-methacryloxypropylethyltrimethoxysilane, γ-methacryloxypropylethyldiethoxysilane, γ-methacryloxypropylethyltriethoxysilane, γ-acryloxypropyltrimethoxysilane, N-β-(aminoethyl)-γ-aminopropylethyldimethoxysilane, N-β-(aminoethyl)-γ-aminopropyltrimethoxysilane, N-β-(aminoethyl)-γ-aminopropyltriethoxysilane, γ-aminopropyltrimethoxysilane, γ-aminopropyltriethoxysilane, N-phenyl-γ-aminopropyltrimethoxysilane, γ-chloropropyltrimethoxysilane, γ-mercaptopropyltrimethoxysilane, γ-mercaptopropylethyldimethoxysilane, bis-(3-[triethoxy siryl]propyl)tetrasulfide, γ-isocyanate propyltriethoxysilane, or a combination comprising at least one of the foregoing.

An amount of the additive used herein is not particularly limited, but may be about 0.1 to about 20 parts, about 0.5 to about 15 parts, or about 1 to about 10 parts by weight, based on 100 parts by weight of the (meth)acryl polymer.

### Method of Preparing Photosensitive Resin Composition

The photosensitive resin composition according to an exemplary embodiment may be obtained by contacting (e.g., agitating or mixing) a (meth)acryl polymer, a photopolymerization initiator, and a crosslinking agent, or other additives, as desired. For example, when the (meth)acryl polymer is prepared by solution polymerization, it may be very suitably used to prepare the photosensitive resin composition in a state of solution without separation or purification. When the filler or pigment is added, the components may be dispersed or mixed using a dispenser, such as a dissolver, a homogenizer, or a 3-roll mill. In addition, as desired, each component or a desired composition may be filtered using a mesh, a membrane filter, or a cartridge filter, for example.

### Adhesive Film

The photosensitive resin composition according to an exemplary embodiment may be utilized very suitably as an adhesive film, by coating and drying on a flexible base film to form a photosensitive film (an adhesive layer). A cover film may be further stacked on the photosensitive coating layer.

An example of the base film may include a resin film containing polyethylene terephthalate (“PET”), polyethylene (“PE”), polypropylene (“PP”), polycarbonate (“PC”), polyestersulfone (“PES”), or polyvinyl chloride (“PVC”). A thickness of the cover film may be about 10 to about 150 micrometers (μm), about 20 to about 140 μm or about 30 to about 130 μm.

As the cover film, a released resin film containing PET, PE, or PP may be used. The thickness of the cover film may be about 10 to about 150 μm, about 20 to about 140 μm, or about 30 to about 130 μm.

Besides the configuration having the base film and the cover film, a configuration having a film between two cover films having different release forces may be used. In other words, after the photosensitive resin composition is coated on the cover film having a large release force, and then dried, the cover film may be further stacked thereon.

The coating of the photosensitive resin composition may be coated by a known method, which would be known to one of skill in the art or may be determined without undue experimentation. An example of a suitable method may include a coating method using a natural coater, a knife belt coater, a floating knife, a knife over roll, a knife over blanket, a spray, a dip coater, a kiss roll, a squeeze roll, a reverse roll, an air blade, a curtain flow coater, a doctor blade, a wire bar, a dye coater, a comma coater, a baker applicator, or a gravure coater. The photosensitive resin composition according to an exemplary embodiment may be coated to an appropriate thickness for its use. The thickness may be about 10 to about 120 μm, about 15 to about 100 μm, or about 20 to about 90 μm.

A viscosity of the photosensitive resin composition according to an exemplary embodiment is not particularly limited, but may be about 0.5 to about 10 Pascal-seconds (Pa·s), about 1 to about 8 Pa·s, or about 4 Pa·s at 25° C. to more easily control the thickness of a layer formed of the composition.

Methods of forming the film (e.g., adhesive layer) on a substrate to be treated using the adhesive film and treating the film (e.g., adhesive layer) are not particularly limited, but may be as follows.

To transfer the film (e.g., adhesive layer) to the substrate to be treated, a transfer roller or a laminator may be used. Further, vacuum compression may be used. The substrate to be treated may be appropriately selected according to the purpose. For example, the substrate may be a resin film comprising polyethylene terephthalate (“PET”), polyethylene (“PE”), polypropylene (“PP”), polycarbonate (“PC”), polysulfone (“PES”), polyvinyl chloride (“PVC”), glass, a silicon wafer, or a metal plate comprising stainless steel.

Afterwards, a photomask having a desired pattern may be disposed on the transferred film (e.g., adhesive layer) and developed by applying radiation, such as UV, visible, far UV, X-ray, or electron beam radiation, to provide the desired pattern. An applied amount of the radiation is not particularly limited, but may be suitably selected, for example, in the range of about 200 to about 1200 milli-Joules per cubic centimeter (mJ/cm³), about 300 to about 1000 mJ/cm³, or about 400 to about 800 mJ/cm³. Examples of a radiation lamp used herein may include a low-pressure mercury lamp, a high-pressure mercury lamp, an ultra-high-pressure mercury lamp, a metal halide lamp, and an argon gas laser.

After a crosslinked resin layer is developed with an alkali development solution, the developed layer may be cleaned with water and dried to dissolve and remove an undesired non-developed part, and only leave the developed part. As a result, the patterned resin layer can be obtained. The alkali development solution may be one generally used to develop a photoresist. For example, the alkali development solution may be an alkali aqueous solution prepared by dissolving at least one of an alkali metal salt, such as sodium hydride, potassium hydride, sodium carbonate, sodium silicate, or sodium metasilicate; an alkyl amine such as ammonia, ethyl amine, n-propyl amine, diethyl amine, di-n-propyl amine, triethylamine, or methyl diethyl amine; an alcohol amine such as dimethyl ethanol amine, or triethanol amine; a heterocyclic amines such as pyrrole, or piperidine; a tetraalkyl ammonium hydroxide such as tetramethyl ammonium hydroxide, or tetraethyl ammonium hydroxide; or an alkali compound such as choline, 1,8-diazabicyclo[5.4.0]-7-undecene, or 1,5-diazabicyclo[4.3.0]-5-nonene; or a combination comprising at least one of the foregoing.

An aqueous solution in which an aqueous organic solvent or a surfactant is added to the alkali aqueous solution in an appropriate amount may be used as the development solution. The development time may be selected based on the type of each component in the composition, the mixing ratio, or the thickness of the film, and may be about 30 to about 360 seconds, or about 60 to about 300 seconds. The development may be performed by a puddle development method, a dipping method, a paddle method, a spray method, or a shower development method. After the development, washing with water may be performed for about 30 to about 90 seconds, and then drying may be performed with air using an air arm or with heat using a hot plate or oven.

The film formed by such a method can be sufficiently cured through only the application of the radiation, and may also be further cured through post treatment such as additional application of radiation or heating according to the use. The exposure may be performed by the application of the radiation. The heating may be performed using a heating device such as a hot plate or oven at a predetermined temperature, for example, about 60 to about 100° C., for about 5 to about 30 minutes for the hot plate, or about 5 to about 60 minutes for the oven.

The photosensitive resin composition according to the exemplary embodiment may be used for bonding an IC chip, or bonding an LCD panel to a touch panel.

### EXAMPLES

Effects, features, advantages, or aspects of the disclosure will be further disclosed with reference to Examples and Comparative Examples. However, the claims of the disclosure shall not limited to the following Examples.

### Example 1

### Introduction of Methacrylate Group (Reactive Double Bond) by Glycidylmethacrylate

In a flask having a refluxing device and agitator, 87 parts by weight of 2-ethylhexyl acrylate, 13 parts by weight of acrylic acid, and 100 parts by weight of methyl ethyl ketone as a solvent were added. Subsequently, the resulting mixture was heated to 72° C., and 0.2 parts by weight of azobisisobutyronitrile (“AIBN”) was added. The mixture was maintained at 72° C., and polymerized for 7 hours. Afterwards, 0.9 parts by weight of glycidyl methacrylate and 1.0 part by weight of tetra-n-butyl ammonium bromide as a reaction catalyst were added, and heated to 80° C. for 6 hours to provide a polymer solution.

### Preparation of Photosensitive Resin Composition

To the polymer solution, 3 parts by weight of IRGACURE 907 (produced by Ciba specialty chemicals) as a photopolymerization initiator and DIPENTAERYTHRITOL HEXAACRYLATE NK ESTER A-DPH (produced by Shin-Nakamura Chemical Co., Ltd) as a crosslinking agent were added and mixed, thereby obtaining a photosensitive resin composition.

### Coating Process

The photosensitive resin composition was dried and then coated to a thickness of 20 μm on a base film, i.e., 125 μm-thick PET film (A4100 produced by TOYOBO Co., Ltd.). Afterwards, the resultant film was dried at 80° C. for 2 minutes. Subsequently, a 38 μm-thick releasable PET film (38E0010BD produced by Fujimori Kogyo Co., Ltd) as a cover film was bonded thereto.

### Exposure Process

On the cover film, a photomask having a ratio of line/space (=100 μm/100 μm) was disposed, and a UV ray was applied to the photomask side. The UV application was performed using PM25C-200 (produced by Ushio Inc.). As an illuminometer, an eye UV illuminometer UVPF-A1 (36 head; produced by Eyegraphics Co., Ltd) was used.

### Development Process and Evaluation

After the UV application, the cover film was released and the resultant film was developed using NMD-3 (produced by Tokyo Ohka Kogyo Co., Ltd). Then, the developed film was washed with water and dried to determine whether the resin layer had patternability and adhesion. The results are summarized in Table 2, which provides the mixture amounts of the components. In Table 2, Tg was calculated using the Fox Equation. Further, the acid value and the content of the reactive double bond were measured from the mixture amounts of the components.

### Evaluation of Adhesion

Adhesion was evaluated by directly touching the adhesive layer. When the layer was sticky, it was marked “◯,” and when the layer was not sticky, it was marked “×.”

### Evaluation of Patternability

Patternability due to development was evaluated by observing an appearance of the adhesive layer. It was observed using an optical microscope with 10-fold magnification whether there was a departed part from the formed pattern or an infused part on the pattern. While not wanting to be bound by theory, it is believed that the departure was caused by a shortage of crosslinking, and the infused part was caused by excessive crosslinking. When the departed part and the infused part were not observed, it was marked “◯,” and when the departed part and the infused part were observed, it was marked “×.”

### Examples 2 to 7

In Examples 2 to 7, a photosensitive resin composition according to an exemplary embodiment was prepared and its properties evaluated by the same method as described in Example 1, except that components were mixed in amounts shown in Table 2. The results are summarized in Table 2 with the mixture amounts.

### Comparative Examples 1 to 4

In Comparative Examples 1 to 4, a photosensitive resin composition was prepared and its properties evaluated by the same method as described in Example 1, except that materials were mixed in amounts shown in Table 3. The results are summarized in Table 3 with the mixture amounts.

### Example 8

### Introduction of Methacrylate Group (Reactive Double Bond) by KARENZ MOI®

In a flask having a refluxing device and agitator, 85 parts by weight of 2-ethylhexyl acrylate, 15 parts by weight of acrylic acid, 5 parts by weight of 2-hydroxy ethyl acrylate, and 75 parts by weight of methyl ethyl ketone as a solvent were added. Subsequently, the resulting mixture was heated to 72° C., and 0.2 parts by weight of azobisisobutyronitrile (“AIBN”) was added. The mixture was maintained at 72° C., and polymerized for 7 hours. Afterwards, 6.7 parts by weight, which is the same amount as that of the hydroxyl group, of isocyanate-containing (meth)acrylate monomer (KARENZ MOI®; produced by Showa Denko K. K.) was added, and heated to 65° C. for 6 hours to provide a polymer solution.

### Preparation of Photosensitive Resin Composition

To the obtained polymer solution, 3 parts by weight of IRGACURE® 907 (Ciba Specialty Chemicals) as a photopolymerization initiator and DIPENTAERYTHRITOL HEXAACRYLATE NK ESTER A-DPH (Shin-nakamura Chemical Co., Ltd) as a crosslinking agent were added to be mixed, thereby obtaining a photosensitive resin composition according to the exemplary embodiment.

### Coating Process

The photosensitive resin composition was dried, and then coated to a thickness of 20 μm on a base film, i.e., 125 μm-thick PET film (A4100 produced by Toyobo Co., Ltd.). Afterwards, the resulting film was dried at 80° C. for 2 minutes. Subsequently, a 38 μm-thick releasable PET film (38E0010BD produced by Fujimori Kogyo Co., Ltd) as a cover film was bonded thereto.

### Exposure/Development Process and Evaluation

On the cover film, a photomask having a ratio of line/space (=100 μm/100 μm) was disposed, and a UV ray was applied to the photomask side. The UV application was performed using PM25C-200 (produced by Ushio Inc.). After the UV application, the cover film was released and the resulting film was developed using NMD-3 (produced by Tokyo Ohka Kogyo Co., Ltd). Then, the developed film was washed with water and dried to observe an appearance and adhesion of the resin layer in the same manner as described in Example 1. The results are summarized in Table 2 with the mixture amounts of the components. In Table 2, Tg was calculated using the Fox Equation. Further, the acid value and the content of the reactive double bond were measured from the mixture amounts of the components.

### Examples 9 to 11

In Examples 9 to 11, a photosensitive resin composition according to an exemplary embodiment was prepared and evaluated as described in Example 8, except that components were used in the amounts shown in Table 2. The results are summarized in Table 2 with the mixture amounts, which are given in parts by weight (“PBW”).

TABLE 2

| | | | Example | | | | | | | | | | |
|---|---|---|---|---|---|---|---|---|---|---|---|---|---|
| | Name | Unit | 1 | 2 | 3 | 4 | 5 | 6 | 7 | 8 | 9 | 10 | 11 |
| Polymer | 2EHA | PBW | 87 | 86 | 80 | 80 | 78 | 83 | 83 | 85 | 84.2 | 75 | 77.5 |
| Composition | AA | PBW | 13 | 14 | 20 | 20 | 22 | 17 | 17 | 15 | 15 | 20 | 20 |
| | 2HEA | PBW | — | — | — | — | — | — | — | 5 | 0.8 | 5 | 2.5 |
| Reactive double | GMA | PBW | 0.9 | 3.8 | 1 | 4 | 12.4 | 3.9 | 6.8 | — | — | — | — |
| bond compound | | | | | | | | | | | | | |
| | MOI | PBW | — | — | — | — | — | — | — | 6.7 | 1.1 | 6.7 | 3.3 |
| Tg | | ° C. | −55 | −54 | −47 | −47 | −45 | −51 | −51 | −50 | −52 | −45 | −46 |
| Weight average | | 10,000 | 2.5 | 2.7 | 3.0 | 3.2 | 3.5 | 2.9 | 2.8 | 15 | 12 | 17 | 13 |
| molecular weight | | | | | | | | | | | | | |
| Acid value | | KOH | 98 | 94 | 151 | 140 | 122 | 117 | 105 | 117 | 117 | 156 | 156 |
| | | mg/g | | | | | | | | | | | |
| Methacrylate | | Mol % | 1 | 4 | 1 | 4 | 12 | 4 | 7 | 6.2 | 1.0 | 5.9 | 3.0 |
| Crosslinking Agent | ADPH | PBW | 15 | 10 | 10 | 10 | 0 | 10 | 5 | 5 | 15 | 5 | 10 |
| Photopolymerization | #907 | PBW | 3 | 3 | 3 | 3 | 3 | 3 | 3 | 3 | 3 | 3 | 3 |
| Initiator | | | | | | | | | | | | | |
| Radiation Dose | | mJ/cm | 1000 | 500 | 1000 | 500 | 100 | 500 | 300 | 300 | 1000 | 300 | 600 |
| Patternability | | | O | O | O | O | O | O | O | O | O | O | O |
| Adhesion | | | O | O | O | O | O | O | O | O | O | O | O |

2EHA: 2-ethylhexyl acrylate
AA: acrylic acid
2HEA: 2-hydroxy ethyl acrylate

GMA: glycidyl methacrylate
MOI: Karenz MOI (Showa Denko K. K.)
ADPH: dipentaerythritolhexacrylate (Shin Nakamura Chemicals)
#907: Irgacure 907 (Ciba Specialty Chemicals)

### Comparative Examples 5 to 8

In Comparative Examples 5 to 8, a photosensitive resin composition according to an embodiment was prepared and evaluated as described in Example 8, except that components were used in the amounts shown in Table 3. The results are summarized in Table 3 with the mixture amounts, which are given in parts by weight (“PBW”).

TABLE 3

| | | | Comparative Example | | | | | | | |
|---|---|---|---|---|---|---|---|---|---|---|
| | Name | Unit | 1 | 2 | 3 | 4 | 5 | 6 | 7 | 8 |
| Polymer Composition | 2EHA | PBW | 91 | 70 | 78 | 70 | 92.1 | 88.5 | 68.5 | 72.1 |
| | AA | PBW | 9 | 30 | 18 | 30 | 7 | 7 | 27 | 27 |
| | 2HEA | PBW | — | — | — | — | 0.9 | 4.5 | 45 | 0.9 |
| Reactive double bond | GMA | PBW | 2.6 | 3.4 | 0 | 22.6 | — | — | — | — |
| compound | | | | | | | | | | |
| | MOI | PBW | — | — | — | — | 1.2 | 6.0 | 6.0 | 1.2 |
| Tg | | ° C. | −59 | −35 | −47 | −35 | −61 | −59 | −37 | −38 |
| Weight average molecular | | 10,000 | 2.5 | 3.5 | 3.3 | 3.5 | 12 | 15 | 15 | 12 |
| weight | | | | | | | | | | |
| Acid Value | | KOH mg/g | 59.7 | 220 | 140 | 140 | 55 | 55 | 210 | 210 |
| Methacrylate | | Mol % | | | 20 | 20 | 1.2 | 6.2 | 49 | 1.0 |
| Crosslinking agent | ADPH | PBW | 10 | 10 | 10 | 10 | 15 | 5 | 5 | 15 |
| Photopolymerization Initiator | #907 | PBW | 3 | 3 | 3 | 3 | 3 | 3 | 3 | 3 |
| Radiation Dose | | mJ/cm | 500 | 500 | 1000 | 1000 | 1000 | 300 | 300 | 1000 |
| Patternability | | | x | O | x | x | x | x | x | O |
| Adhesion | | | x | O | x | x | O | O | x | x |

2EHA: 2-ethylhexyl acrylate
AA: acrylic acid
2HEA: 2-hydroxy ethyl acrylate
GMA: glycidyl methacrylate
MOI: Karenz MOI (Showa Denko K.K.)
ADPH: dipentaerythritolhexacrylate (Shin Nakamura Chemicals)
#907: Irgacure 907 (Ciba Specialty Chemicals)

As illustrated in the results shown in Tables 2 and 3, Examples 1 to 11 all exhibited good patternability and adhesion. According to Examples 1, 2, and 7, in that order, it can be seen that, as the content of the reactive double bond is increased, the UV dose may be reduced and thus patterning may be accomplished with lower energy. In other words, an improved composition corresponding to the UV dose can be selected. Further, Example 5, which does not include a crosslinking agent, also exhibits sufficient patternability and adhesion.

On the other hand, Comparative Examples 1 and 2, which have an acid value less than about 60 or greater than about 180 KOH milligrams per gram, exhibit insufficient patternability and adhesion. Comparative Examples 3 and 4, in which the content of reactive double bond less than about 0.5 or greater than about 18 mole percent, also exhibit insufficient patternability and adhesion. Among Comparative Examples 5 to 8, in which the acid value is less than about 60 or greater than about 180 KOH milligrams per gram, Comparative Examples 5 and 6 having low acid values exhibit insufficient patternability, and Comparative Examples 7 and 8 having high acid values exhibit insufficient adhesion.

While an exemplary embodiment has been disclosed herein, it should be understood that other variations may be possible. Such variations are not to be regarded as a departure from the spirit and scope of exemplary embodiment of the present application, and all such modifications as would be understood to one skilled in the art are to be included within the scope of the following claims.

What is claimed is:

1. A photosensitive resin composition comprising:
about 100 parts by weight of a (meth)acryl polymer comprising
a carboxyl group, and
a reactive double bond on a side chain,
wherein the (meth)acryl polymer has an acid value of about 65 to about 180 KOH milligrams per gram, and a content of a monomer unit comprising the reactive double bond of about 0.5 to about 18 mole percent, based on a total content of monomer units in the (meth)acryl polymer; and
about 0.5 to about 10 parts by weight of a photopolymerization initiator,
wherein the content of the (meth)acryl polymer and the content of the photopolymerization initiator are based on weight of the (meth)acryl polymer.

2. The composition of claim 1, wherein the (meth)acryl polymer has a glass transition temperature of about −60 to about −25° C.

3. The composition of claim 1, wherein the (meth)acryl polymer has a weight average molecular weight of about 10,000 to about 300,000 Daltons.

4. The composition of claim 1, wherein the (meth)acryl polymer is a polymerization product of
a compound comprising a reactive double bond on a side chain and a group capable of reacting with a reactive functional group, and
a copolymerization product of a composition comprising
about 8.0 to 24 parts by weight of a monomer comprising a carboxyl group,
about 0.5 to 15 parts by weight of a monomer comprising the reactive functional group, and
about 91.5 to 61 parts by weight of a monomer capable of copolymerizing the monomer comprising the carboxyl group and the monomer comprising the reactive functional group.

5. The composition of claim 4, wherein the monomer comprising the carboxyl group is (meth)acrylic acid, maleic acid, maleic anhydride, fumaric acid, fumaric anhydride, crotonic acid, itaconic acid, itaconic anhydride, myristoleic acid, palmitoleic acid, oleic acid, or a combination comprising at least one of the foregoing.

6. The composition of claim 4, wherein the monomer comprising the reactive functional group is a (meth)acryl monomer comprising a hydroxyl group, a (meth)acryl monomer comprising an isocyanate group, a (meth)acryl monomer comprising an amino group, a (meth)acryl monomer comprising an epoxy group, or a combination comprising at least one of the foregoing.

7. The composition of claim 6, wherein the monomer comprising the reactive functional group is a (meth)acryl monomer comprising a hydroxyl group.

8. The composition of claim 4, wherein the compound comprising the reactive double bond on a side chain and the group capable of reacting with the reactive functional group is a (meth)acrylic acid ester compound comprising an isocyanate group.

9. The composition of claim 1, wherein the (meth)acryl polymer is a polymerization product of
a compound comprising a reactive double bond and a group capable of reacting with a carboxyl group and
a copolymerization product of a composition comprising
about 8.5 to 39 parts by weight of a monomer comprising a carboxyl group, and
about 91.5 to 61 parts by weight of a monomer capable of being copolymerized with the monomer comprising the carboxyl group.

10. The composition of claim 9, wherein the compound comprising the reactive double bond and the group capable of reacting with the reactive functional group is a (meth)acrylic acid ester compound containing an epoxy group.

11. The composition of claim 1, further comprising a crosslinking agent.

12. An adhesive film comprising the photosensitive resin composition of claim 1.

13. A method of patterning a semiconductor comprising:
disposing the film of claim 12 comprising the photosensitive resin composition on a substrate;
disposing a mask on the film;
irradiating the mask and the film for a time effective to crosslink a portion of the photosensitive resin composition exposed by the mask; and
contacting the irradiated film with an alkali development solution to form a pattern on the semiconductor.

14. A method of patterning a semiconductor, the method comprising:
disposing the photosensitive resin composition of claim 1 on a substrate to form a film comprising the photosensitive composition;
disposing a mask on the film;
irradiating the mask and the film to crosslink an exposed portion of the photosensitive resin composition; and
contacting the irradiated film comprising the crosslinked portion of the photosensitive resin composition with an alkali development solution to form a pattern on the semiconductor.

15. A method of preparing a photosensitive resin composition comprising:
contacting
a monomer comprising a carboxyl group, and
a monomer comprising a reactive functional group, to provide a copolymer;
contacting the copolymer with a compound comprising a reactive double bond and a group capable of reacting with a reactive functional group, to provide a (meth)acryl polymer, wherein the (meth)acryl polymer has an acid value of about 65 to about 180 KOH milligrams per gram, and a content of a monomer unit comprising the reactive double bond of about 0.5 to about 18 mole percent, based on a total content of monomer units in the (meth)acryl polymer; and
contacting 100 parts by weight of the (meth)acryl polymer with about 0.5 to about 10 parts by weight of a photopolymerization initiator, based on the weight of the (meth)acryl polymer, to prepare the photosensitive resin composition.
